(19) United States
(12) Patent Application Publication
(10) Pub. No.: US 2021/0391299 A1
(43) Pub. Date: Dec. 16, 2021

(54) SEMICONDUCTOR DEVICE, METHOD FOR MANUFACTURING SEMICONDUCTOR DEVICE, AND POWER CONVERSION DEVICE

(71) Applicant: Mitsubishi Electric Corporation, Tokyo (JP)

(72) Inventors: Yusuke KAJI, Chiyoda-ku, Tokyo (JP); Seiki HIRAMATSU, Chiyoda-ku, Tokyo (JP)

(73) Assignee: Mitsubishi Electric Corporation, Tokyo (JP)

(21) Appl. No.: 17/283,545

(22) PCT Filed: Dec. 27, 2018
(86) PCT No.: PCT/JP2018/048162

§ 371 Date: Apr. 8, 2021

(51) Int. Cl. H01L 23/00; H01L 25/00; H01L 25/065; H02M 7/5387

(52) U.S. Cl. CPC H01L 24/85; H01L 25/50; H01L 25/18; H01L 24/48; H02M 7/53871; H01L 25/0655

(57) ABSTRACT

The semiconductor device includes: an insulating substrate having metal layers provided at a front surface and a back surface; a semiconductor element having a lower surface joined onto the metal layer on a front surface side, and having an electrode on an upper surface; a base plate; a case member; a terminal member; a wiring member that connects the terminal member and the semiconductor element; a metal thin film member that continuously covers a surface of the terminal member and a surface of the electrode connected by the wiring member, and a surface of the wiring member; and a filling member that covers a surface of the metal thin film member and the insulating substrate exposed from the metal thin film member, and is filled in a region surrounded by the base plate and the case member.

### TECHNICAL FIELD

The present invention relates to a semiconductor device including a stress reduction structure at a joined portion of a wiring material.

### BACKGROUND ART

Inverter devices mounted in industrial equipment, automobiles, and electric railroads are required to be operated under a more severe environment or have a longer life than before, and are required to have a high reliability concerning heat generated during operation of the inverter devices.

In a semiconductor device mounted within an inverter device, a reliability test which simulates operation of the inverter device is performed, and examples thereof include a power cycle test, a heat cycle test, and the like. When a power cycle test or a heat cycle test is performed, stress occurs in a joining member or a wiring member of a semiconductor element mounted in the semiconductor device, and peeling or the like occurs at a joined portion of the joining member or the wiring member, thereby reaching the product life of the semiconductor device.

Thus, in order to solve this problem, it has been disclosed to perform wiring using a wiring material coated with a metal to improve the life of a joining member or a wiring member used for a semiconductor device in a reliability test such as a power cycle test or a heat cycle test (for example, PTL 1). In addition, there has been disclosed a semiconductor device in which an electronic circuit formed of a semiconductor element, a chip capacitor, a chip resistor, a joining material, and a substrate is entirely coated directly with a glass coating film (for example, PTL 2).

### CITATION LIST

### Patent Literature

PTL 1: Japanese Patent National Publication No. 2009-531870

PTL 2: WO 2014/128899

### SUMMARY OF INVENTION

### Technical Problem

However, in the conventional wiring material described in PTL 1, depending on the specification of the metal that coats the wiring member, it is not possible to protect the wiring member against thermal stress. In addition, since other members such as a joining material used simultaneously with the wiring material are not coated, it is not possible to improve reliability. Further, in a conventional electronic control device described in PTL 2, since the glass coating film coats the entire electronic circuit, the glass coating film coats a very wide range. As a result, in a case where the electronic control device (semiconductor device) has a large size, peeling may occur at a portion of the glass coating film. In addition, the peeled portion of the glass coating film is likely to be elongated due to a thermal expansion/shrinkage action, and may reach the semiconductor element, thereby decreasing the reliability of the semiconductor device.

The present invention has been made to solve the aforementioned problems, and an object thereof is to obtain a semiconductor device having reliability improved by reducing thermal stress and suppressing peeling of a wiring member at a joined portion of the wiring member due to the thermal stress.

### Solution to Problem

A semiconductor device in accordance with the present invention is a semiconductor device including: an insulating substrate having metal layers provided at a front surface and a back surface; a semiconductor element having a lower surface joined onto the metal layer on a front surface side of the insulating substrate, and having an electrode on an upper surface; a base plate joined to the back surface of the insulating substrate; a case member that surrounds the insulating substrate together with the base plate; a terminal member provided on an inner peripheral side of the case member; a wiring member that connects the terminal member and the semiconductor element; a metal thin film member that continuously covers the wiring member, and the terminal member and the electrode connected by the wiring member; and a filling member that covers a surface of the metal thin film member and the insulating substrate exposed from the metal thin film member to be in contact therewith, and is filled in a region surrounded by the base plate and the case member.

### Advantageous Effects of Invention

According to the present invention, since a region where the wiring member is joined is continuously coated with the metal thin film member, thermal stress that may occur at the joined portion is reduced and peeling can be suppressed, and thus it is possible to improve the reliability of the semiconductor device.

### BRIEF DESCRIPTION OF DRAWINGS

FIG. 1 is a schematic planar structural view showing a semiconductor device in a first embodiment of the present invention.

FIG. 2 is a schematic cross-sectional structural view showing the semiconductor device in the first embodiment of the present invention.

FIG. 3 is an enlarged schematic cross-sectional structural view of a joined portion of the semiconductor device in the first embodiment of the present invention.

FIG. 4 is a schematic cross-sectional structural view showing steps for manufacturing the semiconductor device in the first embodiment of the present invention.

FIG. 5 is a schematic cross-sectional structural view showing a step for manufacturing the semiconductor device in the first embodiment of the present invention.

FIG. 6 is a schematic cross-sectional structural view showing a step for manufacturing the semiconductor device in the first embodiment of the present invention.

FIG. 7 is a schematic cross-sectional structural view showing a semiconductor device in a second embodiment of the present invention.

FIG. 8 is a schematic cross-sectional structural view showing another semiconductor device in the second embodiment of the present invention.

FIG. 9 is an enlarged schematic cross-sectional structural view of a joined portion of the other semiconductor device in the second embodiment of the present invention.

FIG. 10 is a block diagram showing a configuration of a power conversion system to which a power conversion device in a third embodiment of the present invention is applied.

### DESCRIPTION OF EMBODIMENTS

First, an entire configuration of a semiconductor device of the present invention will be described with reference to the drawings. It should be noted that the drawings are schematic and do not reflect the exact size and the like of the shown components. In addition, the components designated by the same reference numerals are identical or corresponding components. This is common in the entire specification.

### First Embodiment

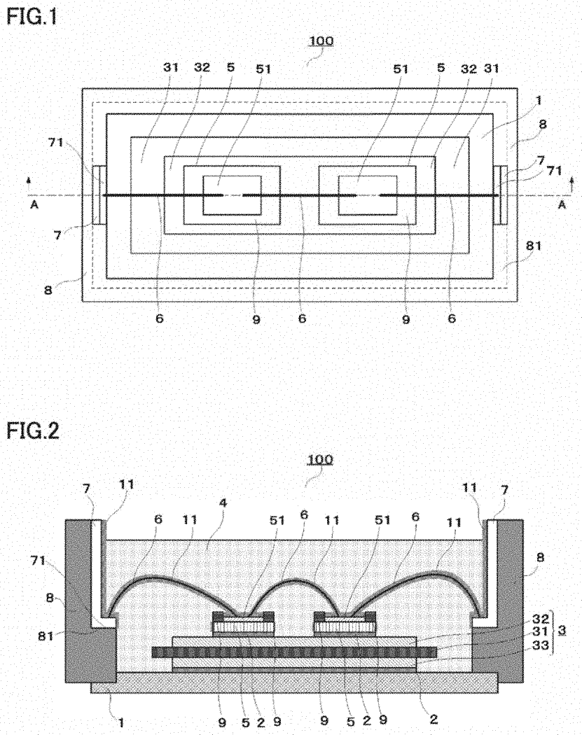

FIG. 1 is a schematic planar structural view showing a semiconductor device in a first embodiment of the present invention. FIG. 2 is a schematic cross-sectional structural view showing the semiconductor device in the first embodiment of the present invention. FIG. 2 is a schematic cross-sectional structural view taken along an alternate long and short dash line AA in FIG. 1. In the drawings, semiconductor device 100 includes a base plate 1, a joining material 2, an insulating substrate 3, a filling member 4, a semiconductor element 5, a bonding wire 6 which is a wiring member, an electrode terminal 7 which is a terminal member, a case material 8 which is a case member, an insulating layer 9 which is an insulating portion, and a metal thin film member 11.

In FIG. 1, case material 8 is joined to an outer peripheral portion of base plate 1 to surround insulating substrate 3. Between the inner periphery of case material 8 and a dotted line is located an electrode terminal arrangement portion 81 at which electrode terminal 7 is arranged. On semiconductor element 5, insulating layer 9 is formed to surround the periphery of an electrode 51. Bonding wire 6 connects electrode terminal 7 and electrode 51 of semiconductor element 5.

In FIG. 2, insulating substrate 3 includes a ceramic plate 31 which is an insulating member, and metal layers 32 and 33 formed on a front surface and a back surface of ceramic plate 31. As ceramic plate 31, silicon nitride (Si₃N₄), aluminum nitride (AlN), aluminum oxide (AlO: alumina), or Zr-containing alumina can be used. In particular, AlN and Si₃N₄ are preferable in terms of thermal conductivity, and Si₃N₄ is more preferable in terms of material strength.

Further, as the insulating member, instead of ceramic plate 31, a resin insulating substrate formed by hardening a resin which contains ceramic powder dispersed therein can also be used. As the ceramic powder, alumina (Al₂O₃), silicon dioxide (SiO₂), aluminum nitride (AlN), boron nitride (BN), silicon nitride (Si₃N₄), or the like can be used. However, the ceramic powder is not limited thereto, and for example, diamond (C), silicon carbide (SiC), boron oxide (B₂O₃), or the like may be used.

Further, as the powder, instead of the ceramic powder, for example, powder made of a resin such as silicone resin or acrylic resin may be used. In addition, as to the shape of the powder, spherical powder is often used. However, the shape of the powder is not limited thereto, and for example, powder such as fragmental powder, granular powder, scale powder, or aggregate powder may be used. Further, as to the amount of the powder filled into the resin, it is only necessary to fill the powder in an amount that allows the resin to obtain required heat dissipation property and insulation property. In addition, as the material for the resin insulating substrate, epoxy resin is generally used. However, the material for the resin insulating substrate is not limited thereto, and for example, polyimide resin, silicone resin, acrylic resin, or the like may be used, and any resin that has both insulation property and adhesiveness can be used.

In semiconductor element 5, electrode 51 is formed on at least an upper surface side of semiconductor element 5. An electrode (not shown) is also formed on a lower surface side of semiconductor element 5. Semiconductor element 5 is mounted on metal layer 32 (an upper surface) on a front surface side of ceramic plate 31. Semiconductor element 5 is electrically joined onto metal layer 32 on the front surface side of ceramic plate 31, via joining material 2 which is solder, for example. In addition, for example, as semiconductor element 5, a power control semiconductor element (switching element) such as a MOSFET (Metal Oxide Semiconductor Field Effect Transistor) or an IGBT (Insulated Gate Bipolar Transistor) for controlling a large current, a reflux diode, or the like is used.

As the material constituting semiconductor element 5, for example, other than silicon (Si), silicon carbide (SiC) which is a wide bandgap semiconductor is applicable. A Si semiconductor element or a SiC semiconductor element using such a material as a substrate material is applied. Further, examples of the wide bandgap semiconductor include a gallium nitride (GaN)-based material, diamond, and the like. In a case where a wide bandgap semiconductor is used, since it has a high allowable current density and a low power loss, it enables downsizing of a device that uses a power semiconductor element.

To join a lower surface of semiconductor element 5 onto metal layer 32 on a front surface side of insulating substrate 3, solder is generally used as joining material 2. However, joining material 2 is not limited to solder, and instead of solder, for example, sintered silver, an electrically conductive adhesive, or a liquid phase diffusion material is applicable. The sintered silver or the liquid phase diffusion material has a high melting temperature when compared with a solder material, and does not remelt when metal layer 33 on a back surface side of insulating substrate 3 is joined onto base plate 1, thus improving the reliability of joining between semiconductor element 5 and insulating substrate 3.

Further, since the sintered silver or the liquid phase diffusion material has a melting temperature higher than that of solder, the operating temperature of semiconductor device 100 can be raised. Since the sintered silver has a thermal conductivity better than that of solder, it improves the heat dissipation property and the reliability of semiconductor element 5. Since the liquid phase diffusion material can perform joining with a load lower than that of the sintered silver, it has a good processability, and can prevent the influence of damage to semiconductor element 5 due to a joining load.

Base plate 1 is joined onto a back surface of metal layer 33 on the back surface side of insulating substrate 3, via joining material 2 such as solder. Base plate 1 serves as a bottom plate of semiconductor device 100, and a region surrounded by base plate 1 and case material 8 arranged around the periphery of base plate 1 is formed. As the material for base plate 1, copper, aluminum, or the like is used. However, the material for base plate 1 is not limited thereto, and for example, an alloy such as an aluminum-silicon carbide alloy (AlSiC) or a copper-molybdenum alloy (CuMo) may be used. Further, metal layer 33 on the back surface side of insulating substrate 3 may also serve as base plate 1.

Case material 8 is required not to cause thermal deformation within the use temperature range of semiconductor device 100, and to maintain insulation property. Thus, for case material 8, a resin having a high softening point, such as a PPS (Poly Phenylene Sulfide) resin or a PBT (Polybutylene terephthalate) resin, is used. Case material 8 includes electrode terminal arrangement portion 81 at which electrode terminal 7 is arranged, on an inner peripheral side of case material 8.

Case material 8 and base plate 1 are bonded using an adhesive (not shown).

The adhesive is provided between a bottom surface of case material 8 and base plate 1. As the material for the adhesive, silicone resin, epoxy resin, or the like is generally used. The adhesive is applied to at least one of case material 8 and base plate 1 to fix case material 8 and base plate 1, and thereafter the adhesive bonds them by thermal hardening.

Electrode terminal 7 is formed on electrode terminal arrangement portion 81 on the inner peripheral side of case material 8 to be in contact with an inner wall of case member 8, and is used to input/output a current and a voltage from/to the outside. Electrode terminal 7 includes, on electrode terminal arrangement portion 81 of case material 8, a connection portion 71 of electrode terminal 7 which is a portion joined to bonding wire 6. As electrode terminal 7, for example, a 0.5 mm-thick copper plate processed into a predetermined shape by etching, die punching, or the like can be used.

Bonding wire 6 establishes electrical connection between metal layers 32 or between semiconductor element 5 and electrode terminal 7. Bonding wire 6 is, for example, a wire rod made of an aluminum alloy or a copper alloy having a wire diameter of 0.1 to 0.5 mm. It should be noted that, although bonding wire 6 is herein used for connection, a ribbon (plate-like member) may be used for connection.

Filling member 4 is filled within the region surrounded by case material 8 and base plate 1 for the purpose of securing insulation property in the inside of semiconductor device 100. Filling member 4 seals insulating substrate 3, metal layers 32 and 33, semiconductor element 5, and bonding wire 6. In a region covered with metal thin film member 11, filling member 4 is filled via metal thin film member 11. As filling member 4, for example, silicone resin is used. However, the filling member is not limited thereto, and may be any material which has desired elastic modulus, heat resistance, and adhesiveness. As the material for filling member 4, for example, epoxy resin, urethane resin, polyimide resin, polyamide resin, acrylic resin, or the like may be used, or a resin material which contains ceramic powder dispersed therein to improve strength and heat dissipation property may be used.

Metal thin film member 11 is formed on surfaces of bonding wire 6 and regions electrically connected by bonding wire 6 (electrode 51 of semiconductor element 5, electrode terminal 7, and connection portion 71 of electrode terminal 7). Metal thin film member 11 continuously coats bonding wire 6 and the surface of electrode 51 of semiconductor element 5, the surface of electrode terminal 7, and the surface of connection portion 71 of the electrode terminal 7, which are the regions electrically connected by bonding wire 6, using a single material. In addition, in the region covered with continuously formed metal thin film member 11, an interface during formation is not formed in metal thin film member 11, and there is no portion that may cause peeling or a crack due to thermal stress.

As the material for metal thin film member 11, a metal material having a higher Young's modulus and a lower linear expansion coefficient than those of bonding wire 6 is applicable. For example, in a case where bonding wire 6 is made of aluminum, gold, silver, titanium, copper, nickel, or the like can be used. Further, in a case where bonding wire 6 is made of copper, nickel is suitable. Metal thin film member 11 desirably has a Young's modulus of 70 GPa or more and 230 GPa or less. For example, in a case where metal thin film member 11 is made of gold, it has a Young's modulus of 78 GPa, and in a case where metal thin film member 11 is made of nickel, it has a Young's modulus of 200 to 220 GPa. Metal thin film member 11 has a thickness of 0.1 μm or more and 50 μm or less. If the thickness of metal thin film member 11 is less than 0.1 μm, metal thin film member 11 may be unable to obtain a sufficient strength. Further, if the thickness of metal thin film member 11 is thicker than 50 μm, metal thin film member 11 is too hard and may cause a crack and the like in other members. Thus, metal thin film member 11 preferably has a thickness of 0.1 μm or more and 50 μm or less.

In addition, considering the steps for manufacturing semiconductor device 100 described in the first embodiment, if there is a time interval from when metal thin film member 11 is formed to when filling member 4 is filled in the region surrounded by base plate 1 and case material 8, metal thin film member 11 may be oxidized. Thus, in a case where there is a long time interval from formation of metal thin film member 11 to filling of filling member 4, the material used for metal thin film member 11 is preferably a material that is less likely to be oxidized, and gold, titanium, nickel, and the like are more suitable. Further, for example, a plating film is applicable as metal thin film member 11.

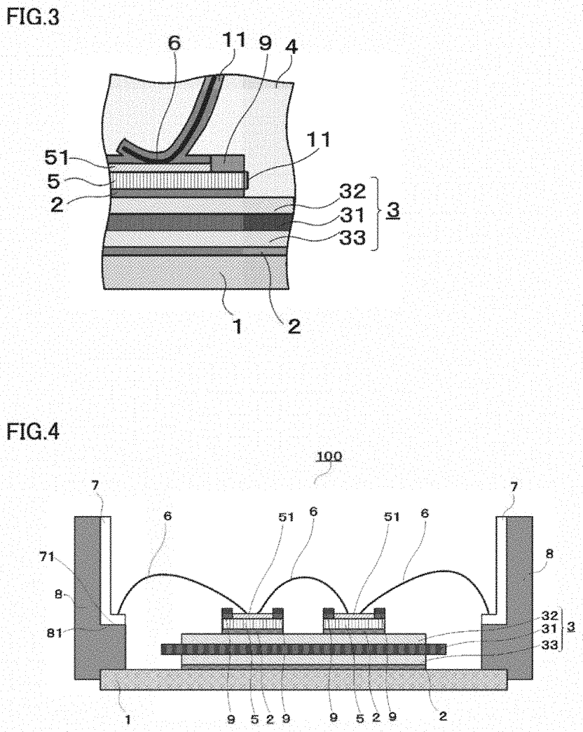

FIG. 3 is an enlarged schematic cross-sectional structural view of a joined portion of the semiconductor device in the first embodiment of the present invention. FIG. 3 is an enlarged cross-sectional structural view in an electrode region of the semiconductor element shown in FIG. 2.

In the drawing, bonding wire 6 is bonded to an upper surface (the surface) of electrode 51 of semiconductor element 5. The surface of electrode 51 surrounded by insulating layer 9, to which bonding wire 6 is bonded, is coated with (formed of) metal thin film member 11 so as to include a joined portion of bonding wire 6. Since insulating layer 9 is formed in an outer peripheral region of semiconductor element 5 to surround electrode 51 on an upper surface of semiconductor element 5, metal thin film member 11 is selectively formed on the surface of electrode 51 of semiconductor element 5. Although metal thin film member 11 is also formed on a side surface of semiconductor element 5, insulating layer 9 formed in the outer peripheral region of semiconductor element 5 suppresses conduction between the upper surface side and the lower surface side of semiconductor element 5 via metal thin film member 11. In addition, metal thin film member 11 is not formed around the periphery of joining material 2. This also suppresses conduction between metal layer 32 on the front surface side of insulating substrate 3 and the lower surface side of semiconductor element 5 as a result of forming metal thin film member 11.

Next, a method for manufacturing semiconductor device 100 of the first embodiment constituted as described above will be described.

FIGS. 4 to 6 are schematic cross-sectional structural views showing steps for manufacturing the semiconductor device in the first embodiment of the present invention. By undergoing the steps in FIGS. 4 to 6, semiconductor device 100 can be manufactured.

First, metal layer 32 is formed on the front surface of ceramic plate 31, and metal layer 33 is formed on the back surface of ceramic plate 31 (an insulating substrate forming step). Joining of metal layers 32 and 33 to ceramic plate 31 is performed by brazing or the like. Since an electric circuit is formed in each of metal layers 32 and 33, they often have different pattern shapes. In such a case, occurrence of thermal stress on the front and back (upper and lower) surfaces of ceramic plate 31 may be suppressed by adjusting the size and the thickness of metal layers 32 and 33.

Then, semiconductor element 5 is electrically joined at a predetermined position (a semiconductor element 5 arrangement region) on metal layer 32 at the front surface of insulating substrate 3, using solder which is joining material 2 (a semiconductor element joining step). By joining semiconductor element 5 onto insulating substrate 3 in this manner, an electric circuit is formed. Joining material 2 is not limited to solder, and other joining materials are also applicable.

Then, a back surface of insulating substrate 3 having semiconductor element 5 joined thereto is joined to a front surface of base plate 1, via solder which is joining material 2 (a base plate joining step). As in the semiconductor element joining step described above, joining can be performed using solder as joining material 2. Joining material 2 is not limited to solder, and other joining materials are also applicable.

Then, an inner peripheral portion side of the bottom surface of case material 8 is brought into contact with an outer peripheral region of the front surface of base plate 1 and is bonded thereto with an adhesive, such that insulating substrate 3 is surrounded by base plate 1 and case material 8 (a case member forming step). On the inner peripheral side of case material 8, electrode terminal 7 is arranged (formed) beforehand at a predetermined position.

Then, as shown in FIG. 4, electrode 51 of semiconductor element 5 joined to metal layer 32 at the front surface of insulating substrate 3 is electrically connected to electrode terminal 7 provided to case material 8 via bonding wire 6 (a wiring member forming step). Similarly, in a case where a plurality of semiconductor elements 5 are used, electrode 51 of one semiconductor element 5 is electrically connected to electrode 51 of another semiconductor element 5 via bonding wire 6 (a wiring member forming step).

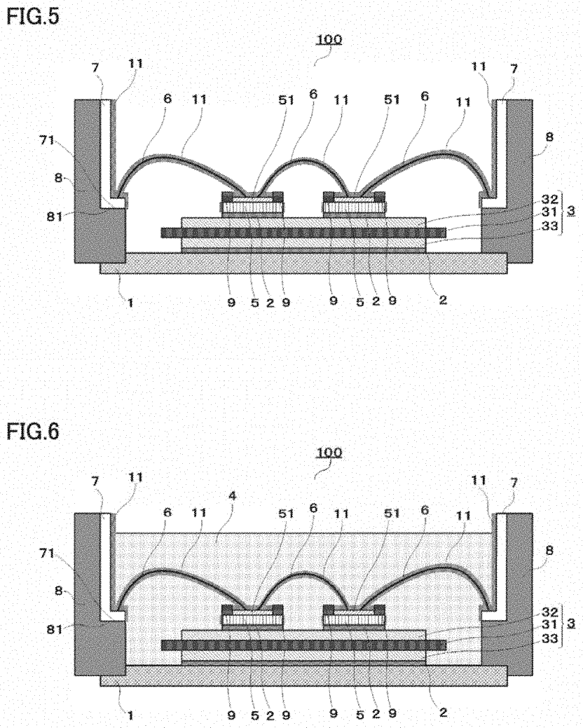

Then, as shown in FIG. 5, metal thin film member 11 is formed on (coats) the surface of bonding wire 6, and the surface of electrode terminal 7 and the surface of electrode 51 of semiconductor element 5 electrically connected by bonding wire 6 (a metal thin film member coating step). Metal thin film member 11 is formed to coat the surface of bonding wire 6 and cover the surface of electrode terminal 7 and the surface of electrode 51 of semiconductor element 5. Here, metal thin film member 11 continuously coats the connection regions connected by bonding wire 6, using a single material.

In semiconductor device 100 in the first embodiment, metal thin film member 11 is formed on the surface of bonding wire 6, a side surface portion of semiconductor element 5, the surface of electrode 51 of semiconductor element 5, and the surface of electrode terminal 7, and is continuously formed using the same material. Thus, in the inside of metal thin film member 11, there is no boundary portion between materials that results from formation of metal thin film member 11 at different times (timings).

Bonding wire 6 on semiconductor element 5 is not connected to metal layer 32 on which semiconductor element 5 is mounted, but is connected to another metal layer or electrode terminal 7 after being connected to the surface of electrode 51 of semiconductor element 5. In this structure, for example, by immersing semiconductor device 100 subjected to the wiring member forming step in a plating solution and applying a voltage to a channel including electrode terminal 7, semiconductor element 5, semiconductor element 5, and electrode terminal 7 connected by bonding wire 6 to perform electric field plating treatment, metal thin film member 11 can be formed on the surface of bonding wire 6, the surface and a side surface of electrode 51 of semiconductor element 5, and the surface of electrode terminal 7, without forming metal thin film member 11 on the surface of metal layer 32 and the periphery of joining material 2.

Further, in the formation of metal thin film member 11, metal thin film member 11 can also be formed on electrode terminal 7, semiconductor element 5, semiconductor element 5, and electrode terminal 7 connected by bonding wire 6, without performing electric field plating. For example, it is also possible to selectively form metal thin film member 11 on electrode terminal 7, semiconductor element 5, semiconductor element 5, and electrode terminal 7 connected by bonding wire 6, by masking a region in which metal thin film member 11 is not to be formed using an insulating material or the like such that metal thin film member 11 is not formed on the surface of metal layer 32, and thereafter performing non-electrolytic plating treatment.

Then, as shown in FIG. 6, filling member 4 is filled in the region surrounded by base plate 1 and case material 8 (a filling member filling step). Filling member 4 is filled within the region surrounded by case material 8 and base plate 1, using a dispenser, for example. As to the filling position (filling amount) of filling member 4, filling member 4 is filled to a position where it covers (seals) bonding wire 6. After filling member 4 is filled, hardening treatment is performed. For example, the hardening treatment for filling member 4 is performed under conditions of 150° C. for two hours (a filling member hardening step). By performing the hardening treatment in this manner, filled filling member 4 is hardened.

By undergoing the above main manufacturing steps, semiconductor device 100 shown in FIG. 1 can be manufactured.

As described above, in semiconductor device 100 in the first embodiment, the surface of bonding wire 6 and the surface of electrode 51 of semiconductor element 5 can be covered with metal thin film member 11 which is a hard material when compared with filling member 4. When a power cycle test, a heat cycle test, or the like is performed, thermal stress is likely to concentrate in the vicinity of a joined portion between bonding wire 6 and semiconductor element 5 or electrode terminal 7 or a bent point of bonding wire 6, and thus peeling or a crack may occur in metal thin film member 11 at this portion, and may deteriorate the original performance of semiconductor device 100.

For example, in a case where metal thin film member 11 is formed through a plurality of discontinuous manufacturing steps (processes), there is an interface between metal thin film members 11 formed in the respective processes. In this case, thermal stress concentrates in the vicinity of a joined portion between bonding wire 6 and semiconductor element 5 or electrode terminal 7 or a bent point of bonding wire 6. In addition, when the interface between metal thin film members 11 exists at this portion, a crack may occur in metal thin film member 11 starting from this interface, and when the crack grows due to a heat cycle, the crack may reach a front surface of bonding wire 6 or semiconductor element 5. In this case, the effect of improving reliability by forming metal thin film member 11 is not fully obtained.

However, in semiconductor device 100 described in the first embodiment, metal thin film member 11 is continuously formed at the portion where stress is likely to concentrate. Thus, stress that may occur in the front surface of bonding wire 6 or semiconductor element 5 can be reduced, and the life (reliability) of semiconductor device 100 in a power cycle test or a heat cycle test can be improved.

In semiconductor device 100 constituted as described above, the surface of bonding wire 6, the surface of electrode 51 of semiconductor element 5, and the surface of electrode terminal 7 are coated with metal thin film member 11 which is a hard material when compared with filling member 4. Thus, stress at a joined portion or a bent portion of bonding wire 6 due to thermal stress can be reduced, and the reliability of semiconductor device 100 can be improved.

### Second Embodiment

A second embodiment is different from the first embodiment in that metal thin film member 11 used in the first embodiment is also provided on the surface of metal layer 32 on the front surface side of insulating substrate 3. Since metal layer 32 of insulating substrate 3 is electrically connected to electrode terminal 7 by bonding wire 6, and metal thin film member 11 is also formed on the surface of metal layer 32 on the front surface side of insulating substrate 3 connected by bonding wire 6 in this manner, stress at a joined portion of bonding wire 6 or a bent portion of bonding wire 6 can be reduced, peeling of metal thin film member 11 can be suppressed, and the reliability of the semiconductor device can be improved. It should be noted that, since the features other than that are the same as those in the first embodiment, the detailed description thereof will be omitted.

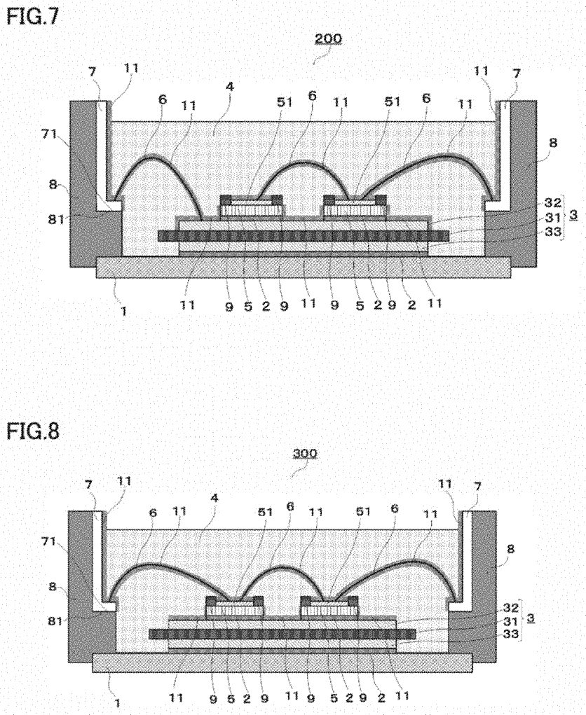

FIG. 7 is a schematic cross-sectional structural view showing a semiconductor device in the second embodiment of the present invention. In the drawing, a semiconductor device 200 includes base plate 1, joining material 2, insulating substrate 3, filling member 4, semiconductor element 5, bonding wire 6 which is a wiring member, electrode terminal 7 which is a terminal member, case material 8 which is a case member, insulating layer 9 which is an insulating portion, and metal thin film member 11.

In FIG. 7, electrode terminal 7 is not only electrically connected to semiconductor element 5 via bonding wire 6, but also is electrically connected to metal layer 32 on the front surface side of insulating substrate 3 via bonding wire 6. Thus, metal thin film member 11 is also formed on the surface of metal layer 32 on the front surface side of insulating substrate 3 to which bonding wire 6 is connected. Also in this case, metal thin film member 11 is continuously formed on the surface of bonding wire 6, the surface of electrode 51 of semiconductor element 5, the surface of electrode terminal 7, and the surface of metal layer 32 on the front surface side of insulating substrate 3, using the same material.

As the material for metal thin film member 11, any metal material having a higher Young's modulus and a lower linear expansion coefficient than those of bonding wire 6 is applicable. Further, by using a material having a Young's modulus higher than that of the material for metal layer 32 on the front surface side of insulating substrate 3, adhesiveness between filling member 4 and metal layer 32 on the front surface side of insulating substrate 3 can be improved, and the effect of improving the reliability of semiconductor element 200 is easily obtained.

As described above, in semiconductor device 200 described in the second embodiment, in addition to the effect described in the first embodiment, metal thin film member 11 is also formed on the surface of metal layer 32 on the front surface side of insulating substrate 3, which suppresses a phenomenon of decreasing the reliability of semiconductor device 200 that occurs due to metal layer 32 on the front surface side of insulating substrate 3.

As the material for metal layer 32 on the front surface side of insulating substrate 3, for example, copper or aluminum is used. In a case where copper is used as the material for metal layer 32 of insulating substrate 3, when the temperature of semiconductor device 200 increases, peeling is likely to occur between copper as metal layer 32 and a silicone gel as filling member 4. However, by applying nickel plating as metal thin film member 11 on the surface of copper as metal layer 32, for example, peeling at an interface between nickel and the silicone gel, that is, peeling between metal layer 32 and metal thin film member 11, can be suppressed.

Further, in a case where aluminum is used as the material for metal layer 32 of insulating substrate 3, since aluminum has a low Young's modulus, when semiconductor device 200 has a high temperature in a power cycle test, a heat cycle test, or the like, there are concerns such as occurrence of deformation of aluminum as metal layer 32 due to thermal stress. However, by forming metal thin film member 11 having a Young's modulus higher than that of metal layer 32 on the surface of metal layer 32, deformation of aluminum as metal layer 32 can be suppressed, and highly reliable semiconductor device 200 can be obtained.

In semiconductor device 200 shown in FIG. 7, metal layer 32 on the front surface side of insulating substrate 3, semiconductor element 5, and electrode terminal 7 are electrically connected via bonding wire 6. Thus, applying a voltage to a channel including electrode terminal 7, metal layer 32 on the front surface side of insulating substrate 3, semiconductor element 5, and electrode terminal 7 connected with each other to perform electric field plating, metal thin film member 11 can also be formed on the surface of metal layer 32 on the front surface side of insulating substrate 3.

FIG. 8 is a schematic cross-sectional structural view showing another semiconductor device in the second embodiment of the present invention. In the drawing, a semiconductor device 300 includes base plate 1, joining material 2, insulating substrate 3, filling member 4, semiconductor element 5, bonding wire 6 which is a wiring member, electrode terminal 7 which is a terminal member, case material 8 which is a case member, insulating layer 9 which is an insulating portion, and metal thin film member 11.

In FIG. 8, although bonding wire 6 is not connected to metal layer 32 on the front surface side of insulating substrate 3, metal thin film member 11 is also formed on the surface of metal layer 32. In such a structure, by forming a mask as an insulating material so as to expose a region in which metal thin film member 11 is to be formed, and performing non-electrolytic plating treatment on the semiconductor device, metal thin film member 11 can also be formed on the surface of metal layer 32 on the front surface side of insulating substrate 3, as shown in FIG. 8.

Although metal thin film member 11 is formed at a plurality of places in semiconductor devices 200 and 300 described in the second embodiment, metal thin film member 11 may be formed at the plurality of places simultaneously or separately. Here, as to the formation state of metal thin film member 11, it is only necessary that continuously formed metal thin film member 11 does not have another metal thin film member 11 formed thereon (i.e., it is only necessary that no interface is formed between a plurality of metal thin film members 11).

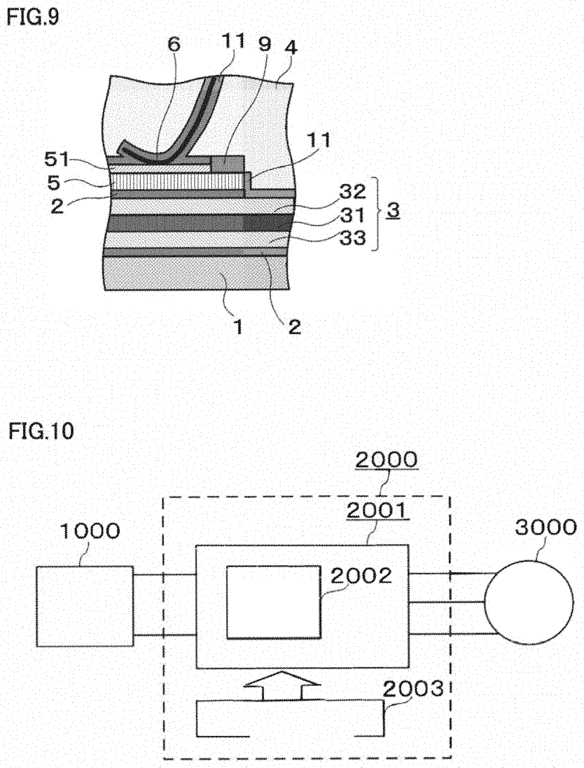

FIG. 9 is an enlarged schematic cross-sectional structural view of a joined portion of the semiconductor device in the second embodiment of the present invention. FIG. 9 is an enlarged cross-sectional structural view in an electrode region of the semiconductor element shown in FIGS. 7 and 8.

In the drawing, bonding wire 6 is bonded to the upper surface (the surface) of electrode 51 of semiconductor element 5. The surface of electrode 51 surrounded by insulating layer 9, to which bonding wire 6 is bonded, is coated with (formed of) metal thin film member 11 so as to include a joined portion of bonding wire 6.

In addition, insulating layer 9 for relaxing an electric field applied on semiconductor element 5 is formed in an outer peripheral end portion of semiconductor element 5, and (first) metal thin film member 11 formed on semiconductor element 5 is formed on electrode 51 that is more inward than insulating layer 9 on semiconductor element 5. Thereby, metal thin film member 11 is formed such that first metal thin film member 11 formed on the upper surface side of semiconductor element 5 is not continuous to second metal thin film member 11 formed from the surface of metal layer 32 on the front surface side of insulating substrate 3 on the lower surface side of semiconductor element 5 to the side surface of semiconductor element 5, with insulating layer 9 serving as a boundary.

If first metal thin film member 11 and second metal thin film member 11 are continuously formed, a plating layer as metal thin film member 11 also exists for example between the upper surface and the lower surface (PN layers) of semiconductor element 5 to be insulated as the semiconductor device, and it becomes structurally difficult to maintain insulation as the semiconductor device. That is, conduction is established between the upper surface and the lower surface of semiconductor element 5.

In addition, if metal thin film member 11 having a high Young's modulus continuously exists, when thermal stress occurs in the semiconductor device in a power cycle test or a heat cycle test, a crack or peeling of metal thin film member 11 may occur at a portion where the stress concentrates. This phenomenon is remarkable especially when the semiconductor device has a large size. If warpage of the semiconductor device occurs due to heat, metal thin film member 11 may be unable to bear stress and may be broken. When metal thin film member 11 is broken due to thermal stress, breakage of metal thin film member 11 may proceed due to a heat cycle, and the broken portion may also reach the upper surface of bonding wire 6 or semiconductor element 5. When the breakage of metal thin film member 11 reaches the upper surface of bonding wire 6 or semiconductor element 5, stress concentrates at the portion where the breakage reaches, and the effect of improving reliability may not be fully obtained.

However, in semiconductor devices 200 and 300 described in the second embodiment, first metal thin film member 11 and second metal thin film member 11 exist independently (discontinuously), with insulating layer 9 serving as a boundary. Thus, the range in which metal thin film member 11 is continuously formed decreases, and even in a case where thermal stress occurs, stress that may occur on metal thin film member 11 is reduced. Thereby, it is possible to obtain a semiconductor device that is highly reliable for a long period of time.

In semiconductor devices 200 and 300 constituted as described above, the surface of bonding wire 6, the surface of electrode 51 of semiconductor element 5, and the surface of electrode terminal 7 are coated with metal thin film member 11 which is a hard material when compared with filling member 4. Thus, stress at a joined portion or a bent portion of bonding wire 6 due to thermal stress can be reduced, and the reliability of semiconductor devices 200 and 300 can be improved.

In addition, since metal thin film member 11 is also formed on the surface of metal layer 32 on the front surface side of insulating substrate 3, stress occurring at an interface between metal thin film member 11 and filling member 4 can be relaxed, peeling of filling member 4 from metal layer 32 is suppressed, and the reliability of semiconductor devices 200 and 300 can be improved.

It should be noted that, since metal thin film member 11 is formed on bonding wire 6 and the joined portion of bonding wire 6 after wiring semiconductor element 5 using bonding wire 6, metal thin film member 11 is not formed at a portion having insulation property, and is formed only at a portion having electrical conductivity. Accordingly, the range in which metal thin film member 11 is continuously formed is limited, and thus occurrence of breakage of metal thin film member 11 due to thermal stress is suppressed even in a large-sized semiconductor device. Thereby, it becomes possible to obtain a semiconductor device that is highly reliable on a long-term basis.

### Third Embodiment

In a third embodiment, a power module in accordance with the first or second embodiment described above is applied to a power conversion device. Although the present invention is not limited to a specific power conversion device, the following description will be given of a case where the present invention is applied to a three-phase inverter, as the third embodiment.

FIG. 10 is a block diagram showing a configuration of a power conversion system to which a power conversion device in the third embodiment of the present invention is applied.

The power conversion system shown in FIG. 10 includes a power source 1000, a power conversion device 2000, and a load 3000. Power source 1000 is a direct current (DC) power source, and supplies DC power to power conversion device 2000. Power source 1000 can be constituted by a variety of devices. For example, it can be constituted by a DC system, a solar cell, or a storage battery, or may be constituted by a rectifier circuit, an AC/DC converter, or the like connected to an alternating current (AC) system. In addition, power source 1000 may be constituted by a DC/DC converter that converts DC power outputted from a DC system into predetermined power.

Power conversion device 2000 is a three-phase inverter connected between power source 1000 and load 3000, and converts the DC power supplied from power source 1000 into AC power and supplies the AC power to load 3000. As shown in FIG. 26, power conversion device 2000 includes a main conversion circuit 2001 that converts the DC power inputted from power source 1000 into AC power and outputs the AC power, and a control circuit 2003 that outputs a control signal for controlling main conversion circuit 2001 to main conversion circuit 2001.

Load 3000 is a three-phase motor driven by the AC power supplied from power conversion device 2000. It should be noted that load 3000 is not limited to a specific purpose, and is a motor mounted in a variety of electric appliances. For example, it is used as a motor for a hybrid automobile, an electric automobile, a railroad vehicle, an elevator, an air conditioner, or the like.

In the following, details of power conversion device 2000 will be described. Main conversion circuit 2001 includes a switching element and a reflux diode (not shown) built in a semiconductor device 2002. In response to switching of the switching element, main conversion circuit 2001 converts the DC power supplied from power source 1000 into AC power and supplies the AC power to load 3000. Although main conversion circuit 2001 may have a variety of specific circuit configurations, main conversion circuit 2001 in accordance with the present embodiment is a two-level three-phase full bridge circuit, and can be constituted by six switching elements and six reflux diodes connected in anti-parallel with the respective switching elements. Main conversion circuit 2001 is constituted by semiconductor device 2002 corresponding to any of the first to fifth embodiments described above that includes the switching elements, the reflux diodes, and the like. Every two switching elements of the six switching elements are connected in series to constitute upper and lower arms, and the respective upper and lower arms constitute respective phases (U-phase, V-phase, and W-phase) of the full bridge circuit. Output terminals of the respective upper and lower arms, that is, three output terminals of main conversion circuit 2001, are connected to load 3000.

Further, main conversion circuit 2001 includes a drive circuit (not shown) that drives each switching element. The drive circuit may be built in semiconductor device 2002, or may be provided separately from semiconductor device 2002. The drive circuit generates a drive signal for driving each switching element of main conversion circuit 2001, and supplies the drive signal to a control electrode of each switching element of main conversion circuit 2001. Specifically, the drive circuit outputs a drive signal for turning on the switching element and a drive signal for turning off the switching element to the control electrode of each switching element according to the control signal from control circuit 2003 described later. When the switching element is kept turned on, the drive signal is a voltage signal that is more than or equal to a threshold voltage of the switching element (ON signal). When the switching element is kept turned off, the drive signal is a voltage signal that is less than or equal to the threshold voltage of the switching element (OFF signal).

Control circuit 2003 controls each switching element of main conversion circuit 2001 such that desired power is supplied to load 3000. Specifically, control circuit 2003 calculates a time at which each switching element of main conversion circuit 2001 is to be turned on (ON time), based on power to be supplied to load 3000. For example, control circuit 2003 can control main conversion circuit 2001 by PWM control that modulates the ON time of each switching element according to a voltage to be outputted. In addition, control circuit 2003 outputs a control command (control signal) to the drive circuit included in main conversion circuit 2001 to output the ON signal to the switching element that is to be turned on and output the OFF signal to the switching element that is to be turned off at each time point. According to the control signal, the drive circuit outputs the ON signal or the OFF signal as the drive signal to the control electrode of each switching element.

In the power conversion device in accordance with the third embodiment constituted as described above, the semiconductor device in accordance with the first or second embodiment is applied as semiconductor device 2002 of main conversion circuit 2001, and thus reliability can be improved.

Although the present embodiment has described an example where the present invention is applied to a two-level three-phase inverter, the present invention is not limited thereto, and can be applied to a variety of power conversion devices. Although a two-level power conversion device is used in the present embodiment, a three-level or multi-level power conversion device may be used. In a case where power is supplied to a single-phase load, the present invention may be applied to a single-phase inverter. Further, in a case where power is supplied to a DC load or the like, the present invention can also be applied to a DC/DC converter, an AC/DC converter, or the like.

Further, the power conversion device to which the present invention is applied is not limited to a case where the load described above is a motor. For example, it can also be used as a power supply device for an electric discharge machine, a laser beam machine, an induction heating cooking device, a non-contact power feeding system, or the like, and can also be used as a power conditioner for a photovoltaic generation system, a power storage system, or the like.

In particular, when SiC is used as semiconductor element 7, a power semiconductor element is operated at a temperature higher than that for Si, in order to make full use of the characteristics of SiC. Since a higher reliability is required in a semiconductor device having a SiC device mounted therein, the advantage of the present invention of achieving a highly reliable semiconductor device becomes more effective.

It should be understood that the embodiments described above are illustrative and non-restrictive in every respect. The scope of the present invention is defined by the scope of the claims, rather than the scope of the embodiments described above, and is intended to include any modifications within the scope and meaning equivalent to the scope of the claims. In addition, an invention may be formed by appropriately combining a plurality of components disclosed in the embodiments described above.

### REFERENCE SIGNS LIST

1: base plate; 2: joining material; 3: insulating substrate; 4: filling member; 5: semiconductor element; 6: bonding wire; 7: electrode terminal; 8: case material; 9: insulating layer; 11: metal thin film member; 31: ceramics plate; 32, 33: metal layer; 51: electrode; 71: connection portion of electrode terminal 7; 81: electrode terminal arrangement portion of the case material; 100, 200, 300, 2002: semiconductor device; 1000: power source; 2000: power conversion device; 2001: main conversion circuit; 2003: control circuit; 3000: load.

1. A semiconductor device comprising:
an insulating substrate having metal layers provided at a front surface and a back surface;
a semiconductor element having a lower surface joined onto the metal layer on a front surface side of the insulating substrate and having an electrode on an upper surface, a side surface of the electrode being surrounded by an insulating portion, and the insulating portion being formed in an outer peripheral region of the upper surface;
a base plate joined to the back surface of the insulating substrate;
a case member that is in contact with the base plate to surround the insulating substrate;
a terminal member provided on an inner peripheral side of the case member;
a wiring member that connects the terminal member and the semiconductor element;
a metal thin film member that continuously covers a surface of the terminal member and a surface of the electrode connected by the wiring member, and a surface of the wiring member; and
a filling member that covers a surface of the metal thin film member and the insulating substrate exposed from the metal thin film member, and is filled in a region surrounded by the base plate and the case member.

2. The semiconductor device according to claim 1, wherein the metal thin film member is also formed on a surface of the metal layer on the front surface side of the insulating substrate connected by the wiring member.

3. The semiconductor device according to claim 1, wherein the metal thin film member is also formed on a surface of the metal layer on the front surface side of the insulating substrate not connected by the wiring member.

4. The semiconductor device according to claim 1, wherein the metal thin film member is a material having a higher Young's modulus and a lower linear expansion coefficient than those of the wiring member.

5. The semiconductor device according to claim 1, wherein the metal thin film member has a Young's modulus of 70 GPa or more and 230 GPa or less.

6. The semiconductor device according to claim 1, wherein the metal thin film member is a plating film.

7. A method for manufacturing a semiconductor device, the method comprising:
a semiconductor element joining step of joining a lower surface of a semiconductor element having an electrode on an upper surface, a side surface of the electrode being surrounded by an insulating portion and the insulating portion being formed in an outer peripheral region of the upper surface, onto a metal layer on a front surface side of an insulating substrate having metal layers provided at a front surface and a back surface;
a base plate joining step of joining a base plate to the back surface of the insulating substrate;
a case member forming step of forming a case member that is in contact with the base plate to surround the insulating substrate, and has a terminal member provided on an inner peripheral side;
a wiring member forming step of connecting the terminal member and the semiconductor element by a wiring member;
a metal thin film member coating step of continuously covering, with a metal thin film member, a surface of the terminal member and a surface of the electrode connected by the wiring member, and a surface of the wiring member; and
a filling member filling step of filling a filling member that covers a surface of the metal thin film member and the insulating substrate exposed from the metal thin film member, in a region surrounded by the base plate and the case member.

8. The method for manufacturing the semiconductor device according to claim 7, wherein, in the metal thin film member coating step, the metal thin film member is also formed on a surface of the metal layer on the front surface side of the insulating substrate not connected by the wiring member.

9. The method for manufacturing the semiconductor device according to claim 7, wherein, in the metal thin film member coating step, the metal thin film member is also formed on a surface of the metal layer on the front surface side of the insulating substrate connected by the wiring member.

10. The method for manufacturing the semiconductor device according to claim 7, wherein the metal thin film member coating step is performed by plating treatment.

11. A power conversion device comprising:
a main conversion circuit that has the semiconductor device according to claim 1, and converts inputted power and outputs the converted power; and
a control circuit that outputs a control signal for controlling the main conversion circuit to the main conversion circuit.

12. The semiconductor device according to claim 1, wherein
a plurality of the semiconductor elements are provided, and
the wiring member covered with the metal thin film member connects between surfaces of the electrodes of the plurality of semiconductor elements.

13. The method for manufacturing the semiconductor device according to claim 7, wherein, in the metal thin film member coating step,
a plurality of the semiconductor elements are provided, and
the metal thin film member is also formed on a surface the wiring member connecting between surfaces of the electrodes of the plurality of semiconductor elements.
